(19) United States
(12) Patent Application Publication
(10) Pub. No.: US 2021/0075383 A1
(43) Pub. Date: Mar. 11, 2021

(54) Amplifier for a transceiver and a transceiver comprising such an amplifier

(71) Applicant: Filtronic Broadband Limited, Sedgefield (GB)

(72) Inventors: Martin Holroyd, Darlington (GB); Jaroslaw Kolodziej, Darlington (GB); Andrew Tucker, Richmond (GB)

(21) Appl. No.: 16/586,003

(22) Filed: Sep. 27, 2019

(30) Foreign Application Priority Data
Sep. 10, 2019 (GB) 1913046.7

(51) Int. Cl. H03F 3/21; H03F 3/213; H01P 3/08; H01P 5/22; H01P 5/20; H04B 1/40

(52) U.S. Cl. CPC H03F 3/211; H03F 3/213; H01P 3/081; H01P 5/22; H01P 5/20; H04B 1/40; H03F 2203/21157; H03F 2200/423; H03F 2203/21142; H03F 2200/171; H03F 2200/451; H03F 2200/255; H03F 2203/21106

(57) ABSTRACT

An amplifier for a transceiver comprising

plurality of power amplifiers arranged on a base, each power amplifier comprising a power amplifier input port and a power amplifier output port;

a planar power splitter arranged on the base, the power splitter comprising a power splitter input port and a plurality of power splitter output ports;

each power amplifier input port being connected to a power splitter output port by a planar transmission line;

each power amplifier output port being connected to a waveguide transition;

a plurality of waveguides each defined by a waveguide wall, each waveguide being arranged within the base, each waveguide transition being connected to waveguide; and,

a waveguide power combiner arranged within the base, each waveguide being connected to the waveguide power combiner.

The present invention relates to an amplifier for a transceiver. More particularly, but not exclusively, the present invention relates to an amplifier for a transceiver comprising a plurality of power amplifiers arranged on a base, the inputs of the power amplifiers being connected to a power splitter, the outputs of the power amplifiers being connected to waveguides which are in turn connected to a waveguide power combiner, the waveguides and waveguide power combiner being arranged in the base. The present invention also relates to a transceiver comprising such an amplifier.

High power transceivers may require that the RF/mmW power of multiple power amplifiers be combined. It is known to achieve this using substrate based planar structures such as Wilkinson splitters or rat race couplers. These planar based structures however exhibit increasing insertion loss with frequency which significantly reduces the power combining efficiency of such assemblies at high frequencies.

An alternative to the use of planar structures as combiners is to use waveguide combiner techniques. These offer lower insertion losses but do not lend themselves to low cost low cost planar transceiver assemblies. Typically the waveguides are realised as separate components which require complex mechanical interfaces with the remainder of the transceiver.

The present invention seeks to overcome the problems of the prior art.

Accordingly, in a first aspect, the present invention provides an amplifier for a transceiver comprising a plurality of power amplifiers arranged on a base, each power amplifier comprising a power amplifier input port and a power amplifier output port;

a planar power splitter arranged on the base, the power splitter comprising a power splitter input port and a plurality of power splitter output ports;

each power amplifier input port being connected to a power splitter output port by a planar transmission line;

each power amplifier output port being connected to a waveguide transition;

a plurality of waveguides each defined by a waveguide wall, each waveguide being arranged within the base, each waveguide transition being connected to waveguide; and,

a waveguide power combiner arranged within the base, each waveguide being connected to the waveguide power combiner.

The amplifier for a transceiver according to the invention uses planar components before the power amplifiers but waveguide components after the power amplifiers. As the waveguide components are an integral part of the amplifier the amplifier has the benefits of low cost manufacture but also low insertion losses after the power amplifiers.

Preferably at least one power amplifier is a MMIC.

Preferably at least one planar transmission line is a microstrip.

Preferably the planar power splitter is a planar rat race splitter.

Alternatively the planar power splitter is a branch line coupler.

Preferably the waveguide power combiner comprises a magic T.

Alternatively the waveguide power combiner comprises a rat race coupler or short slot hybrid combiner.

Preferably the base comprises an upper layer and a lower layer,

the plurality of waveguides extending through the upper layer;

the lower layer having a cavity therein defined by a cavity wall, the cavity wall defining the waveguide power combiner connected to the waveguides.

Preferably the lower layer is a metal.

Alternatively the lower layer is a dielectric, the lower layer being coated with a metal film to define the waveguide power combiner.

Preferably the upper layer is a metal, each waveguide comprising an aperture extending through the upper layer, the sidewall of the aperture defining the waveguide wall.

Preferably the transceiver further comprises a dielectric coating layer arranged on the upper layer.

Alternatively the upper layer is a dielectric.

Preferably at least one waveguide comprises an aperture extending through the upper layer, the wall of the aperture being coated with a metal film which defines the waveguide wall.

Preferably at least one waveguide comprises a plurality of electrically conductive vias extending through the upper layer, the plurality of vias defining the waveguide wall.

In a further aspect the present invention provides a transceiver comprising an amplifier as claimed in any one of claims 1 to 15.

Preferably the transceiver further comprises a signal source connected to the power splitter input port.

Preferably the transceiver further comprises a driver power amplifier connected between the power splitter input port and the signal source.

Preferably the transceiver further comprises an antenna connected to the waveguide power combiner.

Preferably the transceiver comprises at least one of a multiplexer or filter connected between the antenna and waveguide power combiner.

The present invention will now be described by way of example only and not in any limitative sense with reference to the accompanying drawings in which

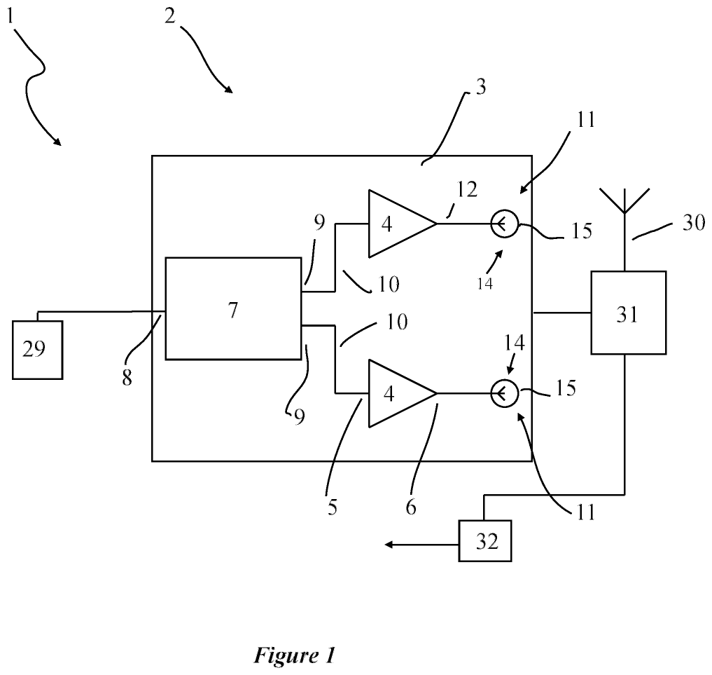

FIG. 1 shows a transceiver according to the invention in plan view;

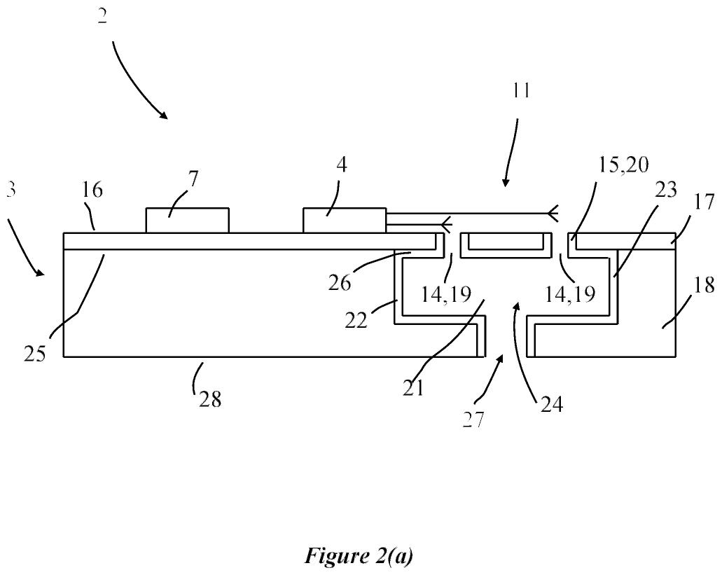

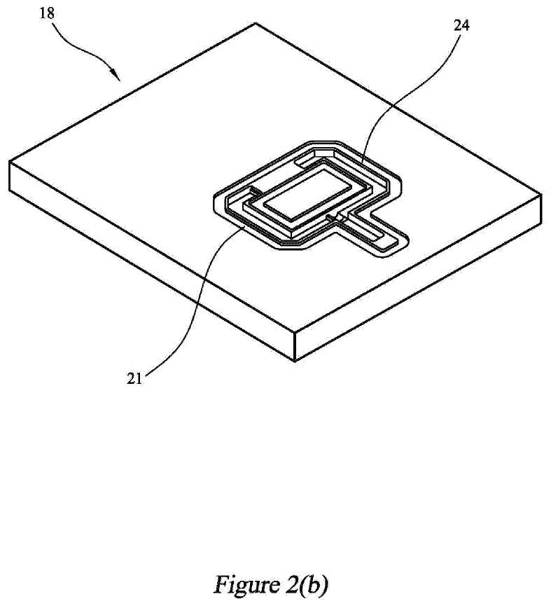

FIG. 2(a) shows the amplifier of the transceiver of FIG. 1 in vertical cross section;

FIG. 2(b) shows the lower layer of the base in perspective view;

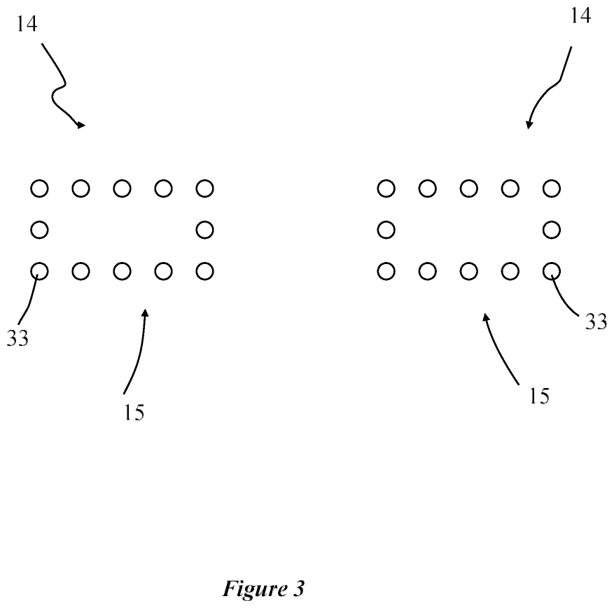

FIG. 3 shows waveguides of a further embodiment of a transceiver according to the invention in plan view;

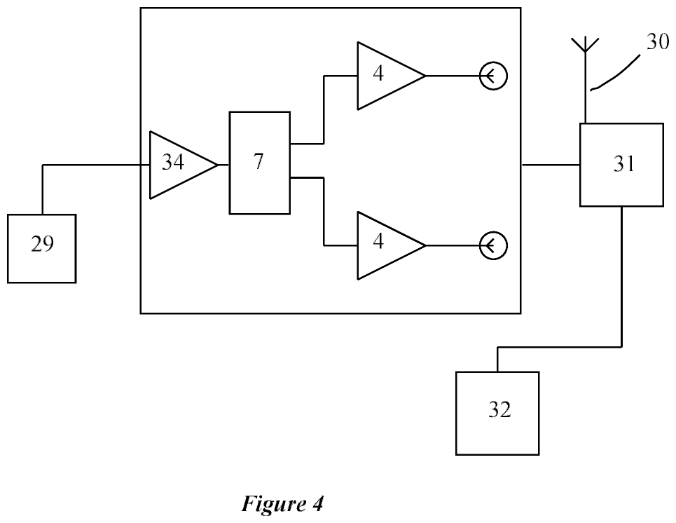

FIG. 4 shows a further embodiment of a transceiver according to the invention; and,

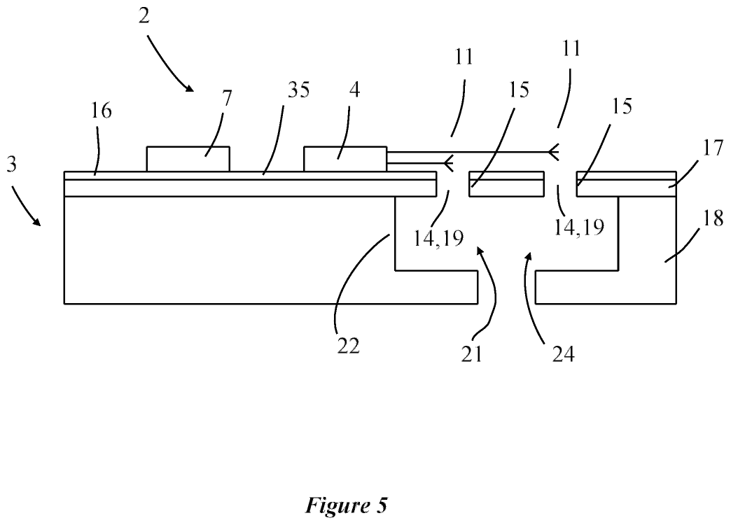

FIG. 5 shows an amplifier of a further embodiment of a transceiver according to the invention.

FIG. 1 shows a transceiver 1 according to the invention in plan view. The transceiver 1 comprises an amplifier 2 according to the invention. The amplifier 2 comprises a base 3. Arranged on the base 3 is a plurality of power amplifiers 4. Each power amplifier 4 comprises a power amplifier input port 5 and a power amplifier output port 6. Typically, the power amplifiers 4 are MMICs.

Also arranged on the base 3 is a planar power splitter 7. In this embodiment the planar power splitter 7 is a planar rat race splitter realised in a planar technology such as microstrip or stripline. The operation of such a power splitter 7 is well known and will not be described in detail. The planar power splitter 7 comprises a power splitter input port 8 and a plurality of power splitter output ports 9. Power provided to the power splitter input port 8 is divided and exits the power splitter output ports 9. Each power amplifier input port 5 is connected to a power splitter output port 9 by a planar transmission line 10. Substrate based planar transmission lines are again known in the art and so will not be described in detail. In this embodiment each planar transmission line 10 is a microstrip.

Connected to each power amplifier output port 6 is a waveguide transition 11. Each waveguide transition 11 comprises a microstrip 12 which terminates in an antenna 13 which extends over the mouth of a waveguide 14 defined by a waveguide wall 15. The waveguides 14 are described in more detail with reference to FIGS. 2(a) and 2(b) below.

Shown in FIG. 2(a) in vertical cross section is the amplifier 2 of the transceiver 1 shown in FIG. 1. Arranged on the top face 16 of the base 3 are the planar power splitter 7, the power amplifiers 4 and waveguide transitions 11. The base 3 comprises upper and lower dielectric layers 17,18. Extending through the upper layer 17 is a plurality of apertures 19. The side walls of each aperture 19 is coated with a metal film 20 which defines the waveguide wall 15 of each waveguide 14. Arranged within the lower layer 18 is a cavity 21 defined by a cavity wall 22. The cavity wall 22 is also coated with a metal film 23. The cavity 21 is shaped as a waveguide power combiner 24 connected to the waveguides 14.

A portion of the lower face 25 of the upper layer 17 is coated with a further metal film 26 which closes the cavity 21. The waveguide power combiner 24 comprises an output port 27 which exits the lower face 28 of the base 3.

FIG. 2(b) shows the lower layer 18 of the base 3 in perspective view showing the waveguide power combiner 24. In this embodiment the waveguide power combiner 24 is a ‘magic T’. The operation of a magic T is known in the art and so will not be described in detail.

Returning now to FIG. 1, the transceiver 1 further comprises a signal source 29 connected to the power splitter input port 8. The transmitter 1 further comprises an antenna 30 connected to the output port 27 of the waveguide power combiner 24 via a multiplexer 31. A receiver 32 is also connected to the multiplexer 31. In use the signal source 29 passes an RF or microwave signal to the input port 8 of the of the planar power splitter 7. The planar power splitter 7 splits the signal and provides it to each power amplifier input port 5. Each power amplifier 4 amplifies its received signal, passes the amplified signal to its waveguide transition 11, and then to a waveguide 14 in the base 3. The signals which pass along the waveguides 14 are combined by the waveguide power combiner 24 and then to the output port 27. From the output port 27 the signal passes to the antenna 30 via the multiplexer 31. When the transceiver 1 receives a signal the signal travels from the antenna 30 to the multiplexer 31 and then to the receiver 32.

In the embodiment of the transceiver 1 shown in FIGS. 1, 2(a) and 2(b) the waveguides 14 comprise apertures 19 that extend through the upper layer 17. In an alternative embodiment of the invention each waveguide 14 comprises a plurality of electrically conductive vias 33 that extend through the upper layer 17. The vias 33 define the waveguide wall 15. Such waveguides 14 are shown in plan view in FIG. 3. The vias 33 are typically metal. The vias 33 may be hollow or solid.

FIG. 4 shows an alternative embodiment of a transceiver 1 in plan view. This is similar to that of FIG. 1 except it further comprises a driver power amplifier 34 arranged between the signal source 29 and planar power splitter 7.

FIG. 5 shows the amplifier 2 of a further embodiment of a transceiver according to the invention in vertical cross section. In this embodiment both upper and lower layers 17,18 of the base 3 are metal. A plurality of apertures 19 extend through the upper layer 17. The side walls of the apertures 19 define the waveguide walls 15. The lower layer 18 comprises a cavity 21 defined by a cavity wall 22. The cavity wall 22 defines the waveguide power combiner 24. Arranged on the top face 16 of the base 3 is a dielectric coating 35. The power splitter 7, power amplifiers 4 and waveguide transitions 11 are arranged on the dielectric coating 35.

In the above embodiments the waveguide power combiner 24 is a magic T. In alternative embodiments the transceiver 1 is not so limited and may comprise a functional equivalent such as a rat race coupler or short slot hybrid combiner.

In an alternative embodiment of the invention the planar power splitter 7 is a branch line coupler.

In a further alternative embodiment of the invention the planar transmission lines 10 are striplines.

In a further alternative embodiment of the invention the transceiver 1 comprises a filter connected between the antenna 30 and waveguide power combiner 24 as an alternative or in addition to the multiplexer 31.

1. An amplifier for a transceiver comprising
a plurality of power amplifiers arranged on a base, each power amplifier of the plurality of power amplifiers comprising a power amplifier input port and a power amplifier output port;
a planar power splitter arranged on the base, the planar power splitter comprising a power splitter input port and a plurality of power splitter output ports;
each power amplifier input port being connected to a power splitter output port of the plurality of power splitter output ports by a planar transmission line;
each power amplifier output port being connected to a waveguide transition;
a plurality of waveguides, wherein each waveguide of the plurality of waveguides is defined by a waveguide wall, each waveguide of the plurality of waveguides being arranged within the base, each waveguide transition being connected to waveguide; and
a waveguide power combiner arranged within the base, each waveguide being connected to the waveguide power combiner.

2. The amplifier for the transceiver as claimed in claim 1, wherein at least one power amplifier is a monolithic microwave integrated circuit.

3. The amplifier for the transceiver as claimed in claim 1, wherein at least one planar transmission line is a microstrip.

4. The amplifier for the transceiver as claimed in claim 1, wherein the planar power splitter is a planar rat race splitter.

5. The amplifier for the transceiver as claimed in claim 1, wherein the planar power splitter is a branch line coupler.

6. The amplifier for the transceiver as claimed in claim 1, wherein the waveguide power combiner comprises a magic T.

7. The amplifier for the transceiver as claimed in claim 1, wherein the waveguide power combiner comprises a rat race coupler or short slot hybrid combiner.

8. The amplifier for the transceiver as claimed in claim 1, wherein the base comprises an upper layer and a lower layer,
the plurality of waveguides extending through the upper layer; and
the lower layer having a cavity therein defined by a cavity wall, the cavity wall defining the waveguide power combiner connected to the waveguides.

9. The amplifier for the transceiver as claimed in claim 8, wherein the lower layer is a metal.

10. The amplifier for the transceiver as claimed in claim 8, wherein the lower layer is a dielectric, the lower layer being coated with a metal film to define the waveguide power combiner.

11. The amplifier for the transceiver as claimed in claim 8, wherein the upper layer is a metal, each waveguide of the plurality of waveguides comprising an aperture extending through the upper layer, a side wall of the aperture defining the waveguide wall.

12. The amplifier for the transceiver as claimed in claim 11, further comprising a dielectric coating layer arranged on the upper layer.

13. The amplifier for the transceiver as claimed in claim 8, wherein the upper layer is a dielectric.

14. The amplifier for the transceiver as claimed in claim 13, wherein at least one waveguide of the plurality of waveguides comprises an aperture extending through the upper layer, a side wall of the aperture being coated with a metal film which defines the waveguide wall.

15. The amplifier for the transceiver as claimed in claim 13 wherein at least one waveguide of the plurality of waveguides comprises a plurality of electrically conductive vias extending through the upper layer, the plurality of electrically conductive vias defining the waveguide wall.

16. A transceiver comprising:
a plurality of power amplifiers arranged on a base, each power amplifier comprising a power amplifier input port and a power amplifier output port;
a planar power splitter arranged on the base, the power splitter comprising a power splitter input port and a plurality of power splitter output ports;
each power amplifier input port being connected to a power splitter output port by a planar transmission line;
each power amplifier output port being connected to a waveguide transition;
a plurality of waveguides each defined by a waveguide wall, each waveguide being arranged within the base, each waveguide transition being connected to waveguide; and
a waveguide power combiner arranged within the base, each waveguide being connected to the waveguide power combiner.

17. The transceiver as claimed in claim 16, further comprising a signal source connected to the power splitter input port.

18. The transceiver as claimed in claim 17, further comprising a driver power amplifier connected between the power splitter input port and the signal source.

19. The transceiver as claimed in claim 16, further comprising an antenna connected to the waveguide power combiner.

20. The transceiver as claimed in claim 19, further comprising at least one of a multiplexer and filter connected between the antenna and the waveguide power combiner.
